(19) United States
(12) Patent Application Publication
(10) Pub. No.: US 2025/0357365 A1
(43) Pub. Date: Nov. 20, 2025

(54) CHIP PACKAGE ASSEMBLY WITH SURFACE MOUNTED COMPONENT PROTECTION

(71) Applicant: Advanced Micro Devices, Inc., Santa Clara, CA (US)

(72) Inventors: Chia-Chun MIAO, Santa Clara, CA (US); Christopher Michael HELBERG, Austin, TX (US); Yuan David MA, Austin, TX (US); Himanshu A. BAL, San Diego, CA (US); Cheng Hua FAN, Kaohsiung (TW); Sungjun IM, San Jose, CA (US); Xuqi FENG, Suzhou (CN)

(21) Appl. No.: 18/664,668

(22) Filed: May 15, 2024

(51) Int. Cl. H01L 23/00; H01L 23/42; H01L 25/16

(52) U.S. Cl. CPC H01L 23/562; H01L 23/42; H01L 24/32; H01L 25/16; H01L 24/16; H01L 24/73; H01L 2224/16225; H01L 2224/32225; H01L 2224/32245; H01L 2224/73204

(57) ABSTRACT

A chip package assembly includes a package substrate having a top surface and an IC die mounted to the top surface of the package substrate. A stiffener includes a top portion and a bottom portion, and the bottom portion is mounted on the top surface of the package substrate. A dam is disposed on the top surface of the package substrate. A cavity is defined between the dam and the bottom portion. A surface mounted component is mounted on the package substrate and inside the cavity. The top portion is mounted on the bottom portion and across the cavity.

### TECHNICAL FIELD

Embodiments of the present disclosure generally relate to chip package assemblies and techniques for manufacturing the same. In particular, embodiments of the present disclosure generally relate to chip package assemblies having features that minimize contact of surface mounted components with thermal interface materials.

### BACKGROUND ART

Electronic devices, such as tablets, computers, server, high performance computing data centers, smart phones, and control systems, among others, often employ electronic components which leverage chip package assemblies for increased functionality and higher component density. Conventional chip package assemblies include one or more stacked components such as integrated circuit (IC) dies, through-silicon-via (TSV) interposer, and a package substrate, with the chip package assembly itself stacked on a printed circuit board (PCB). The IC dies may include memory, logic, MEMS, RF or other IC device.

Surface mounted components, such as capacitors, resistors, and the like, are often utilized in chip package assemblies. The surface mounted components are typically mounted to a package substrate laterally to the side and spaced away from the dies that are mounted to the package substrate. The surface mounted components are typically mounted between the dies and a stiffener, if utilized, which is generally mounted at the periphery of the of the package substrate.

Recently, liquid metal thermal interface materials (“TIM”) have been used to dissipate heat away from the dies. The liquid metal TIM is disposed between the dies and a heat sink to facilitate heat transfer from the dies to the heat sink. One of the challenges faced with implementing TIM is residue from the liquid metal may cause an electrical short. For example, the liquid metal residue may come into contact with a surface mounted component mounted on the package substrate and cause the electrical short. To minimize the potential for electrical short, the surface mounted components are spaced away from the dies, which undesirably reduces the space available for dies or undesirably requires a larger package substrate.

Therefore, a need exists for an improved chip package assembly that minimizes liquid metal TIM contact with surface mounted components.

### SUMMARY

In one embodiment, a chip package assembly includes a package substrate having a top surface and an IC die mounted to the top surface of the package substrate. A stiffener includes a top portion and a bottom portion, and the bottom portion is mounted on the top surface of the package substrate. A dam is disposed on the top surface of the package substrate. A cavity is defined between the dam and the bottom portion. A surface mounted component is mounted on the package substrate and inside the cavity. The top portion is mounted on the bottom portion and disposed above the cavity.

In another example, a method of fabricating a chip package assembly includes coupling an IC die to a top surface of a package substrate and coupling a surface mounted component to the package substrate. The method also includes disposing a bottom portion of a stiffener assembly on the top surface of the package substrate and a dam on the package substrate. The dam and the bottom portion define a cavity housing the surface mounted component. A top portion of the stiffener assembly is mounted on the bottom portion to enclose the cavity.

In another example, a chip package assembly includes a package substrate having a top surface and an IC die mounted to the top surface of the package substrate. A stiffener is mounted on the top surface of the package substrate, and a dam is disposed on the top surface of the package substrate. The dam and the stiffener are arranged to define a cavity. A surface mounted component is mounted on the package substrate and inside the cavity. A lid disposed on the stiffener and the die, wherein the lid covers a top of the cavity.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional schematic view of an integrated chip package mounted on a printed circuit board.

FIG. 2 is a partial schematic view of the integrated chip package of FIG. 1.

FIG. 3 is a partial schematic view of another embodiment of an integrated chip package.

FIG. 4 is a partial schematic view of another embodiment of an integrated chip package.

FIG. 5 is a partial schematic top view of a stiffener assembly of the integrated chip package of FIG. 4.

FIG. 6 is a schematic top view of the chip package of FIG. 4 shown without the heat spreader.

FIG. 7 is another schematic top view of the chip package of FIG. 4 shown without the heat spreader.

FIG. 8 is a partial schematic view of another embodiment of an integrated chip package.

FIG. 9 is a flow diagram of a method of forming a chip package assembly.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the disclosure generally provide a chip package assembly including a package substrate and an IC die mounted to the top surface of the package substrate. A bottom portion of a stiffener and a dam are arranged on the package substrate to define a cavity for housing a surface mounted component. A top portion of the stiffener is mounted on the bottom portion and covers the cavity. Thus, the stiffener disclosed herein minimize the potential for residue from liquid metal TIM to contact the surface mounted components, thereby limiting electrical short caused by liquid metal TIM contacting the surface mounted components. Additionally, examples of the stiffener disclosed can be efficiently assembled by attaching a top portion to a bottom portion. In this respect, the cavity housing the surface mounted components can be formed without the use of a costly etching process for a stainless-steel stiffener ring.

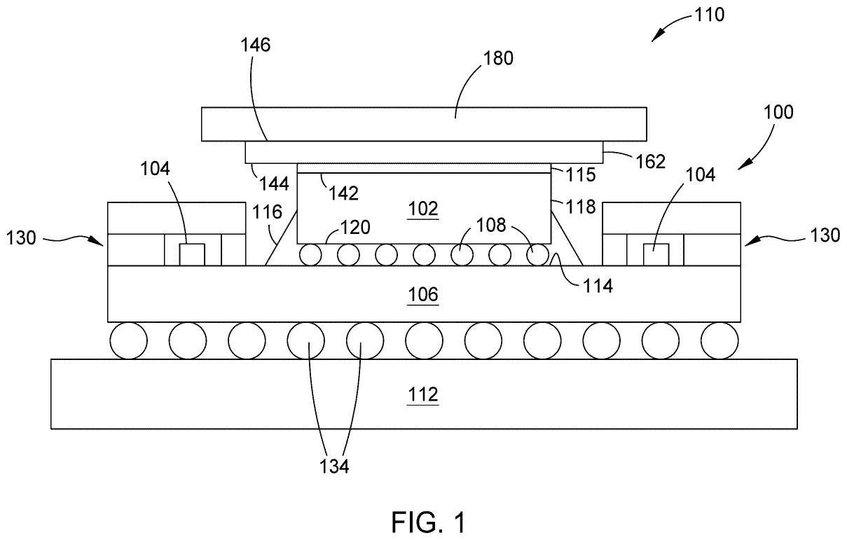

Turning now to FIG. 1, an integrated circuit electronic device 110 is schematically illustrated having an exemplary integrated chip (IC) package assembly 100 mounted on a printed circuit board (PCB) 112 by solder balls 134.

The chip package assembly 100 generally includes a die 102, a package substrate 106, one or more surface mounted components 104, a dam 140, and a stiffener assembly 130. The IC die 102 may be programmable logic devices, such as field programmable gate arrays (FPGA), memory devices, optical devices, processors or other IC logic structures. Optical devices include photo-detectors, lasers, optical sources, and the like. Although one IC die 102 is shown in FIG. 1, the number of IC dies may range from one to as many as can be fit within the chip package assembly 100 in order to meet design criteria.

The IC die 102 is connected directly to the package substrate 106, for example as flip chip ball grid array (FCBGA), ball grid array (BGA), wire bond and the like. In another example, the die 102 of the chip package assembly 100 may be connected to the package substrate 106 via the interposer (not shown). It is contemplated that the chip package assembly 100 may have other configurations.

A bottom 120 of the IC die 102 is connected to a top surface 114 of the package substrate 106 by solder connections 108. The solder connections 108, such as micro-bumps, mechanically and electrically connect the circuitry of the IC die 102 to the circuitry of the package substrate 106.

Underfill 116 is disposed in the interstitial spaces between the bottom 120 of the IC die 102 and the top surface 114 of the package substrate 106, thereby providing structural rigidity to the chip package assembly 100. The underfill 116 also surrounds and protects the solder connections 108 between the die 102 and the package substrate 106. The underfill 116 may be an epoxy or other suitable material. The underfill 116 may additionally include fillers, for example, inorganic fillers such as silica (SiO₂).

The top surface 142 of the die 102 faces a bottom surface 144 of a heat spreader 162. The heat spreader 162 is fabricated from rigid thermally conductive material. Materials suitable for fabricating the heat spreader 162 include stainless steel, copper, nickel-plated copper and aluminum, among other suitable thermally conductive materials. The heat spreader 162 may be structurally coupled to the package substrate 106 or PCB 112 to increase the rigidity of the chip package assembly 100. Optionally, the heat spreader 162 may be dynamically mounted to the PCB 112 in a manner that allows relative movement between the heat spreader 162 to the underlying chip package assembly 100.

Thermal interface material (TIM) 115 may be disposed between the top surface 142 of the IC die 102 and the bottom surface 144 of the heat spreader 162 to enhance heat transfer therebetween. In one example, the TIM 115 may be a liquid metal TIM. Exemplary liquid metals include gallium, indium, bismuth, tin, and their alloys. The liquid metals may have a melting point near room temperature. In another example, the TIM 115 may be a thermally conductive grease, thermal gel or thermal epoxy, such as, packaging component attach adhesives. Optionally, the TIM 115 may be a plurality of thermally conductive particles dispersed in a carrier material. The carrier material may be comprised of the thermally conductive grease, thermal gel or thermal epoxy. The thermally conductive particles may include one or more of metal, carbon or other highly thermally conductive particles, metal fibers, metal powder, metal balls, fillers or additives that enhance the heat transfer of the carrier material of the TIM 115.

In some embodiments, a heat transfer device 180 is mounted above a top surface 146 of the heat spreader 162. The heat transfer device 180 provides an efficient heat transfer path away from the chip package assembly 100, thus providing robust thermal management of the IC die 102 within the electronic device 110. In some embodiments, the heat spreader 162 is integral with the heat transfer device 180 or is optional.

Exemplary heat transfer devices 180 include a cooling plate, one or more optional passive cooling devices, one or more active cooling devices, or combinations thereof. The cooling plate may be fabricated from rigid thermally conductive material. Materials suitable for fabricating the cooling plate include stainless steel, copper, nickel-plated copper and aluminum, among other suitable thermally conductive materials. Suitable active cooling devices include a heat transfer structure or system that utilizes an open or circulated fluid circuit for transfer heat; examples of which include heat exchangers and fan forced air systems. Active cooling devices may also incorporate passive cooling elements such as a passive fluid element (i.e., a heat pipe) with active air cooling (i.e., fan driven air) and/or active liquid cooling (i.e., a heat exchanger interfaced with the passive cooling elements). In contrast, a passive cooling device is fluidless or has fluid trapped in a sealed volume for heat transfer, examples of which include heat sinks and heat pipes. In some examples, the passive and active cooling devices are mounted in or on a top surface of the cooling plate.

The surface mounted components 104 are coupled to the top surface 114 of the package substrate 106 at a location spaced apart from the side 118 of the die 102. The surface mounted components 104 may be one or more of a capacitor, diode, resistor, inductor, or other suitable discrete circuit element. The surface mounted components 104 are soldered to a conductor residing on or in the package substrate 106, and are coupled to the circuitry of the die 102 through the circuitry of the package substrate 106.

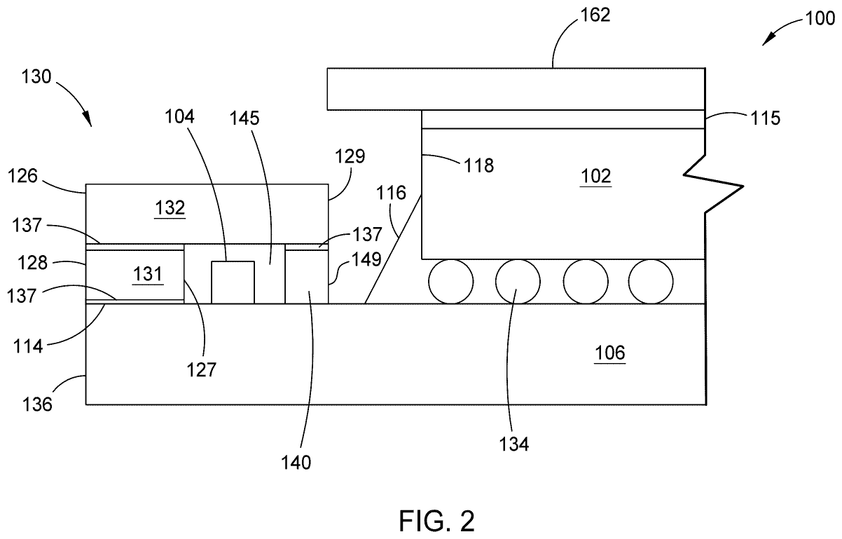

FIG. 2 is an enlarged, partial sectional view of the chip package assembly 100. In one embodiment, a dam 140 is disposed on the top surface 114 of the package substrate 106 between the side 118 of the die 102 and the surface mounted components 104. The dam 140 extends upward from the top surface 114 of the package substrate 106 in a manner that prevents residue from the liquid metal TIM 115 from coming into contact with the surface mounted components 104. In one example, the dam 140 has a height that is greater than or equal to the height of the surface mounted component 104. The dam 140 may also act as a barrier against the underfill 116 from coming into contact with the surface mounted components 104.

In one embodiment, the dam 140 may be part of the top surface 114 of the package substrate 106. For example, the dam 140 may be formed during manufacturing of the package substrate 106. It is contemplated the dam 140 can be formed before the surface mounted components 104 are formed. In another embodiment, the dam 140 may be a separate component disposed or formed on the top surface 114 of the package substrate 106. For example, the dam 140 can be formed from a barrier material coating and cured using ultraviolet light. In another example, the dam 140 may be made from one or more dam layers, which are generally fabricated from a dielectric material. The dam layers may be deposited utilizing any suitable technique. In one example, the dam layers are printed on the top surface 114 of the package substrate 106, such as by ink jet or screen printing. In some examples, the dam 140 is made from a metal, a polymer, or combinations thereof.

The stiffener assembly 130 is generally mounted at a peripheral edge 136 of the package substrate 106 and circumscribes the IC die 102. The stiffener assembly 130 provides mechanical support which helps prevent the chip package assembly 100 from bowing and warping. The stiffener assembly 130 may be made of ceramic, metal or other various inorganic materials, such as aluminum oxide (Al₂O₃), aluminum nitride (AlN), silicon nitride (SiN), silicon (Si), copper (Cu), aluminum (Al), and stainless steel, among other materials. The stiffener assembly 130 can also be made of organic materials such as copper-clad laminate.

In one embodiment, the stiffener assembly 130 includes a bottom portion 131 and a top portion 132 disposed above the bottom portion 131. The bottom portion 131 of the stiffener assembly 130 is attached to the top surface 114 of the package substrate 106 using an adhesive 137. The adhesive 137 may be an epoxy or other suitable bonding material. In the example illustrated in FIG. 2, an outer side 128 of the bottom portion 131 is substantially aligned with the peripheral edge 136 of the package substrate 106 while an inner side 127 of the bottom portion 131 faces and is spaced apart from the surface mounted components 104. The bottom portion 131 has a height that is greater than or equal to the height of the surface mounted component 104. In this example, the bottom portion 131 has the same height as the dam 140.

The top portion 132 of the stiffener assembly 130 is disposed above the bottom portion 131 and the dam 140. In this example, an outer side 126 of the top portion 132 is substantially aligned with the outer side 128 of the bottom portion 131 while an inner side 129 of the top portion 132 is substantially aligned with the inner side 149 of the dam 140. It is contemplated the inner and outer sides 129, 126 do not need to be aligned with outer side 128 of the bottom portion 131 and the inner side 149 of the dam 140, so long as the top portion 132 overlaps both the bottom portion 131 and the dam 140. In this example, the top portion 132 is attached to the bottom portion 131 and the dam 140 at a height above the surface mounted components 104. The top portion 132 may be attached to the bottom portion 131 and the dam 140 using an adhesive 137. In some examples, one or both of the top portion 132 and the bottom portion 131 are made from a metal, a polymer, or combinations thereof.

Thus, the arrangement of the bottom portion 131, top portion 132, and the dam 140 advantageously forms a cavity 145 to enclose the surface mounted components 104, thereby shielding the surface mounted components 104 from contact with residue from the liquid metal TIM 115 or other material such as the underfill 116. Because this arrangement reduces the probability of the liquid metal residue from coming in contact with the surface mounted components 104, the surface mounted components 104 may be mounted at a shorter distance from the side 118 of the die 102. This shorter distance advantageously allows for a smaller package substrate 106 and/or enables faster communication and better signal integrity between the surface mounted components 104 and the die 102.

Additionally, the stiffener assembly 130 can be efficiently assembled by attaching a top portion 132 to a bottom portion 131. In this respect, the cavity 145 can be formed without the use of a costly etching process for a stainless-steel stiffener ring. Further, because the top portion 132 is attached to the bottom portion 131 at a height above the surface mounted components 104, the potential for damaging the surface mounted components 104 during attachment of the stiffener assembly 130 is minimized.

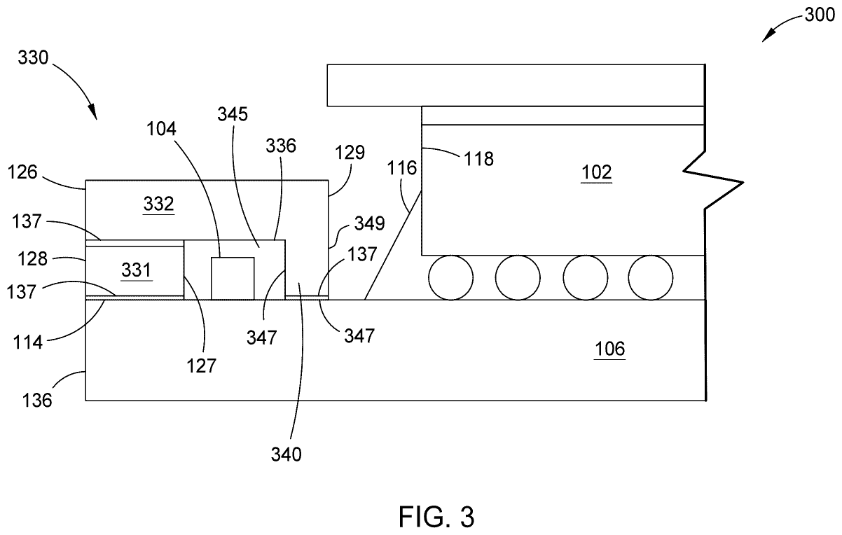

FIG. 3 is an enlarged, partial schematic view of another embodiment of an integrated chip package assembly 300. Although only a portion of the chip package assembly 300 is illustrated in FIG. 3, the chip package assembly 300 is substantially the same as the chip package assembly 100 depicted in FIGS. 1-2, except wherein the dam 340 extends from the top portion 332 of the stiffener assembly 330 instead of the package substrate 106.

Referring to FIG. 3, the surface mounted components 104 are coupled to the top surface 114 of the package substrate 106 at a location spaced apart from the side 118 of the die 102. The surface mounted components 104 may be one or more of a capacitor, diode, resistor, inductor, or other suitable discrete circuit element.

The stiffener assembly 330 is generally mounted at a peripheral edge 136 of the package substrate 106 and circumscribes the IC die 102. The stiffener assembly 330 provides mechanical support which helps prevent the chip package assembly 100 from bowing and warping.

In one embodiment, the stiffener assembly 330 includes a bottom portion 331 and a top portion 332 disposed above the bottom portion 331. The bottom portion 331 of the stiffener assembly 330 is attached to the top surface 114 of the package substrate 106 using an adhesive 137. The adhesive 137 may be an epoxy or other suitable bonding material. In the example illustrated in FIG. 3, an outer side 128 of the bottom portion 331 is substantially aligned with the peripheral edge 136 of the package substrate 106 while an inner side 127 of the bottom portion 331 faces and is spaced apart from the surface mounted components 104. The bottom portion 331 has a height that is greater than or equal to the height of the surface mounted component 104.

The top portion 332 of the stiffener assembly 330 is disposed above the bottom portion 331. In this example, an outer side 126 of the top portion 332 is substantially aligned with the outer side 128 of the bottom portion 331. An inner side 129 of the top portion 332 faces the die 102 and extends inwardly past the surface mounted components 104. The top portion 332 includes a dam 340 extending downward from a bottom surface 336 of the top portion 332. The outer side 346 of the dam 340 is inward of the surface mounted components 104, and the inner side 349 of the dam 340 may be substantially aligned with the inner side 129 of the top portion 332. The bottom side 347 of the dam 340 can be attached to the top surface 114 of the package substrate 106 using an adhesive 137. The dam 340 may be integral with the top portion 332 or attached to the top portion 332 before attachment to the bottom portion 331 and the package substrate 106. In this example, the top portion 332 and the dam 340 form a reverse “L” shape. It is contemplated the outer side 126 does not need to be aligned with the outer side 128 of the bottom portion 331, so long as the top portion 332 overlaps the bottom portion 331. In this manner, the bottom portion 331, top portion 332, and the dam 340 advantageously form a cavity 345 to enclose the surface mounted components 104, thereby shielding the surface mounted components 104 from contact with liquid metal residue or other material such as the underfill 116.

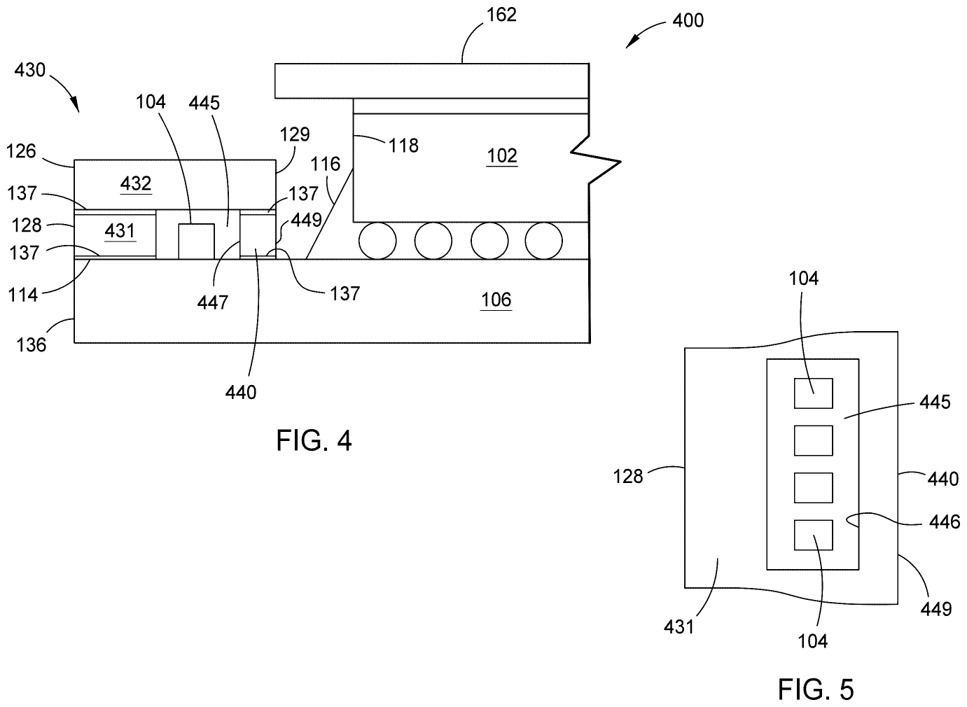

FIG. 4 is an enlarged, partial schematic view of another embodiment of an integrated chip package assembly 400. Although only a portion of the chip package assembly 400 is illustrated in FIG. 4, the chip package assembly 400 is substantially the same as the chip package assembly 100 depicted in FIGS. 1-2, except wherein the stiffener assembly 430 and the dam 440 have a different configuration.

Referring to FIG. 4, the surface mounted components 104 are coupled to the top surface 114 of the package substrate 106 at a location spaced apart from the side 118 of the die 102. The surface mounted components 104 may be one or more of a capacitor, diode, resistor, inductor, or other suitable discrete circuit element.

The stiffener assembly 430 is generally mounted at a peripheral edge 136 of the package substrate 106 and circumscribes the IC die 102. The stiffener assembly 430 provides mechanical support which helps prevent the chip package assembly 100 from bowing and warping.

In one embodiment, the stiffener assembly 430 includes a bottom portion 431 and a top portion 432 disposed above the bottom portion 431. The bottom portion 431 of the stiffener assembly 430 is attached to the top surface 114 of the package substrate 106 using an adhesive 137. The adhesive 137 may be an epoxy or other suitable bonding material. In the example illustrated in FIG. 4, a cavity 445 is formed in the bottom portion 431 to accommodate the surface mounting components 104. FIG. 5 is a top view of the bottom portion 431 of the stiffener assembly 430 and the surface mounted components 104 with the top portion 432 removed for clarity. As shown, the surface mounted components 104 are enclosed in the cavity 445 of the bottom portion 431. The bottom portion 431 includes a dam 440 formed by a side of the bottom portion 431 defining the cavity 445 and closest to the die 102. The dam 440 has an outer side 446 facing the cavity 445 and an inner side 449 facing the die 102. The dam 440 may be integral with the bottom portion 431 or attached to the bottom portion 431 before the bottom portion 431 is attached to the package substrate 106. The outer side 128 of the bottom portion 431 is substantially aligned with the peripheral edge 136 of the package substrate 106. The bottom portion 431 has a height that is greater than or equal to the height of the surface mounted component 104. The bottom portion 431, including the dam 440, is attached to the top surface 114 of the package substrate 106 using adhesive 137.

The top portion 432 of the stiffener assembly 430 is disposed above the bottom portion 431. In this example, an outer side 126 of the top portion 432 is substantially aligned with the outer side 128 of the bottom portion 431, and an inner side 129 of the top portion 432 is substantially aligned with the inner side 449 of the dam 440. It is contemplated the inner and outer sides 129, 126 do not need to be aligned with outer side 128 of the bottom portion 431 and the inner side 449 of the dam 440, so long as the top portion 432 overlaps both the bottom portion 431, including the dam 440. In this example, the top portion 432 is attached to the bottom portion 431 and the dam 440 at a height above the surface mounted components 104. The top portion 432 may be attached to the bottom portion 431 and the dam 440 using an adhesive 137. In this manner, top portion 432 and the bottom portion 431, including the dam 440, advantageously enclose the surface mounted components 104, thereby shielding the surface mounted components 104 from contact with liquid metal residue or other material such as the underfill 116.

FIG. 6 is a schematic top view of the chip package assembly 400 of FIG. 4 shown without the heat spreader 162. The die 102 is surrounded by the top portion 432 of the stiffener assembly 430. The inner side 129 of the top portion 432 is spaced away from the side 118 of the die 102. In this example, all of the cavities 445 and the surface mounted components 104 disposed therein (both shown in phantom) are covered and shielded by the top portion 432 of the stiffener assembly 430.

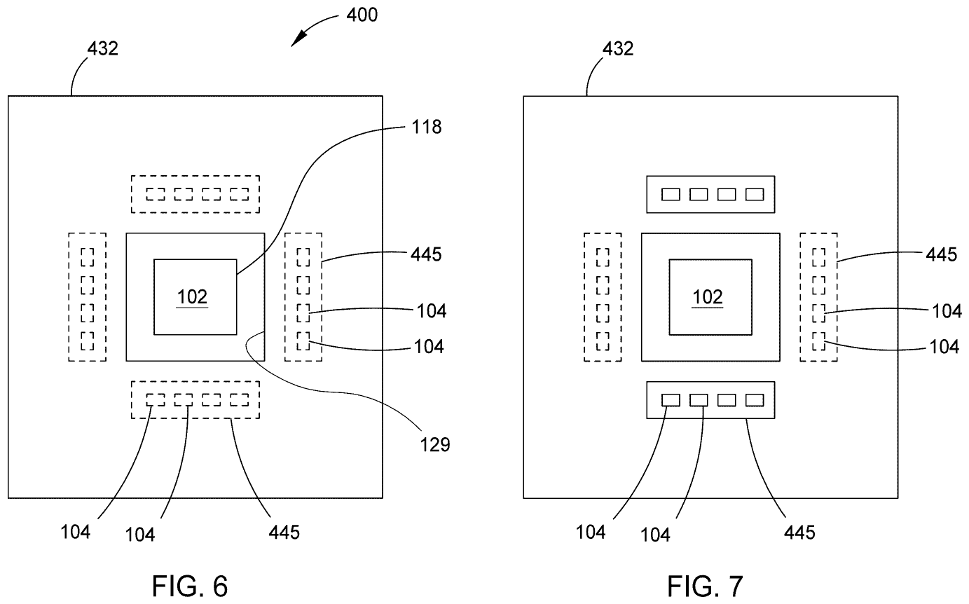

It is contemplated the top portion 432 of the stiffener assembly 430 can be configured to cover one or more of the cavities 445 and leave one or more of the cavities open. FIG. 7 is another schematic top view of the chip package assembly 400 of FIG. 4 shown without the heat spreader 162. In this example, two of the cavities 445 are covered (shown in phantom) by the top portion 432, and two of the cavities 445 are not covered (shown in solid line) by the top portion 432. While the cavities 445 above and below are shown uncovered, it must be noted that any one of the cavities 445 can remain open. It is further noted that one or more of the cavities 145, 345, 545 can be left uncovered by the stiffener assemblies 130, 330 or the lid 560 of a chip package assembly 500 (discussed below).

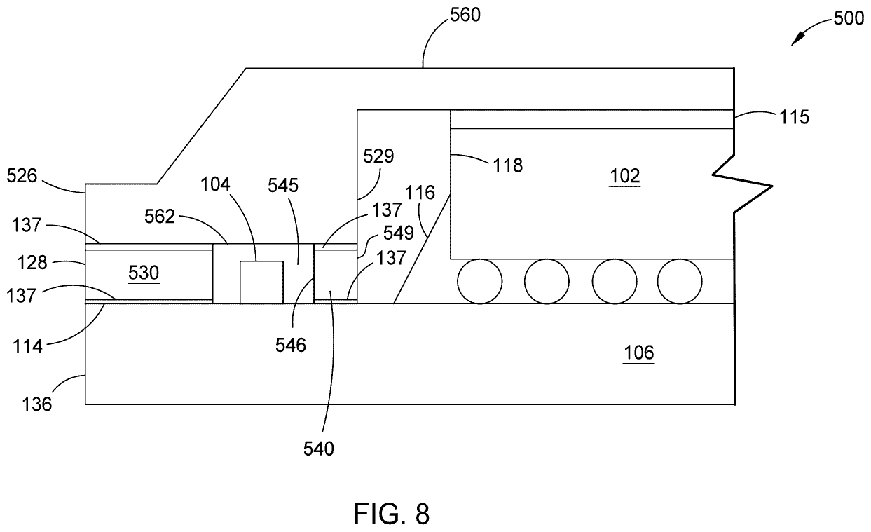

FIG. 8 is an enlarged, partial schematic view of another embodiment of an integrated chip package assembly 500. Although only a portion of the chip package assembly 500 is illustrated in FIG. 8, the chip package assembly 500 is substantially the same as the chip package assembly 500 depicted in FIG. 4, except wherein the stiffener 530 and the dam 540 have a different configuration.

Referring to FIG. 8, the surface mounted components 104 are coupled to the top surface 114 of the package substrate 106 at a location spaced apart from the side 118 of the die 102. The surface mounted components 104 may be one or more of a capacitor, diode, resistor, inductor, or other suitable discrete circuit element.

The stiffener 530 is generally mounted at a peripheral edge 136 of the package substrate 106 and circumscribes the IC die 102. The stiffener 530 provides mechanical support which helps prevent the chip package assembly 100 from bowing and warping.

In one embodiment, a stiffener 530 is attached to the top surface 114 of the package substrate 106 using an adhesive 137. The adhesive 137 may be an epoxy or other suitable bonding material. In the example illustrated in FIG. 8, a cavity 545 is formed in the stiffener 530 to accommodate the surface mounting components 104. In this respect, the surface mounted components 104 are enclosed in the cavity 545 of the stiffener 530. The stiffener 530 includes a dam 540 formed by a side of the stiffener 530 defining the cavity 545 and closest to the die 102. The dam 540 has an inner side 546 facing the cavity 545 and an inner side 549 facing the die 102. The dam 540 may be integral with the stiffener 530 or attached to the stiffener 530 before the stiffener 530 is attached to the package substrate 106. The outer side 128 of the stiffener 530 is substantially aligned with the peripheral edge 136 of the package substrate 106. The stiffener 530 has a height that is greater than or equal to the height of the surface mounted component 104. The stiffener 530, including the dam 540, is attached to the top surface 114 of the package substrate 106 using adhesive 137.

In this embodiment, a lid 560 is disposed above the stiffener 530 to enclose the surface mounted components 104. The lid 560 is disposed above the die 102, and a TIM 115 such as liquid metal is disposed between the lid 560 and the die 102. The lid 560 may be fabricated from metals, ceramics, thermoplastics, glass reinforced plastics, and carbon reinforced materials, among others. In some examples, the lid 560 may be made of ceramic, metal or other various inorganic materials, such as aluminum oxide (Al₂O₃), aluminum nitride (AlN), silicon nitride (SiN), silicon (Si), copper (Cu), aluminum (Al), and stainless steel, among other materials. In one example, the lid 560 is made from copper with nickel plating. In another example, the lid 560 is made from stainless steel. In some embodiments, the lid 560 may be provided as an alternative or in addition to the heat spreader 162 shown in FIG. 1. When fabricated from a thermally conductive material such as a metal, the lid 560 is may be utilized as a heat spreader (such as heat spreader 162 and/or a heat transfer device (such as heat transfer device 180) that enhances thermal management (i.e., temperature control) of the IC die 102.

In this example, the ends of the lid 560 extend downward to engage the stiffener 530. As shown, a bottom side 562 of the lid 560 is disposed above the stiffener 530 and across the cavity 545. An outer side 526 of the lid 560 is substantially aligned with the outer side 128 of the stiffener 530, and an inner side 529 of the lid 560 is substantially aligned with the inner side 549 of the dam 540. It is contemplated the inner and outer sides 529, 526 do not need to be aligned with outer side 128 of the stiffener 530 and the inner side 549 of the dam 540, so long as the lid 560 overlaps the stiffener 530 and across the cavity 545. In this example, the lid 560 is attached to the stiffener 530, including the dam 540 at a height above the surface mounted components 104. The lid 560 may be attached to the stiffener 530 using an adhesive 137. In this manner, the lid 560 and the stiffener 530, including the dam 540, advantageously enclose the surface mounted components 104, thereby shielding the surface mounted components 104 from contact with liquid metal residue or other material such as the underfill 116.

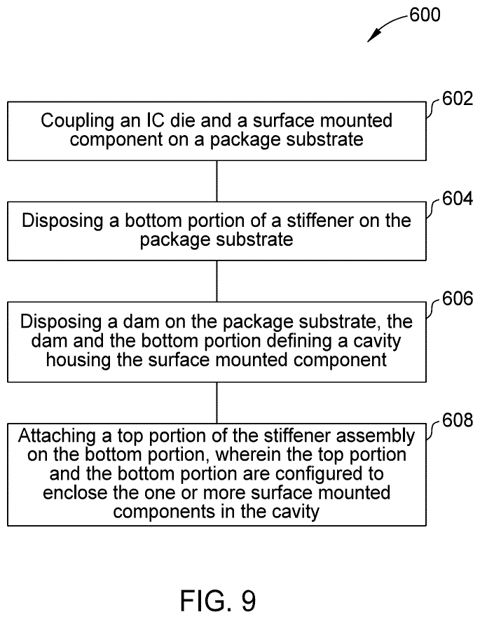

FIG. 9 is a flow diagram of a method 600 of forming a chip package assembly, such as the chip package assemblies 100, 300, 400 described above, among others. The method 600 begins at operation 602 by mounting one or more dies 102 and one or more surface mounted components 104 on a top surface 114 of a package substrate 106. The die 102 and surface mounted components 104 may be mounted to the top surface 114 of the package substrate 106 using conventional or other suitable techniques.

At operation 604, a dam 140 is disposed on the top surface of the package substrate 106. In some embodiments, the dam 140 is preformed on the package substrate 106 and extends upward from the top surface 114 of the package substrate 106, such as the example illustrated in FIG. 2. In one example, the dam 140 is formed during manufacturing of the package substrate 106 and before the die 102 is mounted. The dam 140 may be formed utilizing the methods described above, or other suitable technique. The dam 140 is positioned between the surface mounted components 104 and the die 102.

At operation 606, a bottom portion 131, 331, 431 of the stiffener assembly 130, 330, 430 is attached to the top surface 114 of the package substrate 106 using an adhesive 137. In one example, the bottom portion 131, 331 is positioned on the outer side of the surface mounted components 104 and opposite the die 102. In the example shown in FIG. 2, the bottom portion 131 is positioned such that a cavity 145 is formed between the bottom portion 131 and the dam 140 on the package substrate 106, and the surface mounted components 104 are positioned inside the cavity 145. In another example, such as the example illustrated in FIG. 3, the dam 340 forms a part of the top portion 332 of the stiffener assembly 330 and extends downwardly toward the package substrate 106. In another example, such as the example illustrated in FIG. 4, the bottom portion 431 of the stiffener assembly 430 includes a cavity 445 formed therein. The bottom portion 431 is positioned such that the surface mounted components 104 are disposed in the cavity 445. In this example, the dam 440 is integral with the bottom portion 431 and forms a side of the bottom portion 431 defining the cavity 445. The bottom portion 131, 331, 431 and the dam 140, 440 have a height greater than the height of the surface mounted components 104.

At operation 608, a top portion 132, 332, 432 of the stiffener assembly 130, 330, 430 is attached above the bottom portion 131, 331, 431. The top portion 132, 332, 432 of the stiffener assembly 130, 330, 430 can be attached above the bottom portion 131, 331, 431 using an adhesive. In the example illustrated in FIG. 2, the top portion 132 is attached above the bottom portion 131 and the dam 140, when the dam 140 is present on the package substrate 106. In this manner, the top portion 132, the bottom portion 131, and the dam 140 encloses the surface mounted components 104 inside the cavity 145. In another example, such as in FIG. 3, the dam 340 extends downwardly from the top portion 332 and is located between the surface mounted components 104 and the die 102, thereby forming a cavity 345 with the bottom portion 331 to house the surface mounted components 104. A bottom surface of the top portion 332 is attached to the bottom portion 331, and the bottom surface of the dam 340 is attached to the top surface of the package substrate 106. In another example, such as in FIG. 4, the top portion 432 is disposed across the cavity 445 formed in the bottom portion 431 of the stiffener assembly 430, thereby enclosing the surface mounted components 104 in the cavity 445. In this manner, the top portion 132, 332, 432 and the bottom portion 131, 331, 431 of the stiffener assembly 130, 330, 430 cooperate to shield the surface mounted components 104 from contact with residue from the liquid metal TIM 115 or other material such as the underfill 116. In another example, instead of a top portion, the cavity 145, 345, 445 can be closed by attaching the lid 560 of the chip package assembly 500 to the stiffener 530, as illustrated in FIG. 8.

Thus, examples of the chip package assemblies disclosed herein minimize the potential for liquid metal residue to come into contact with surface mounted components. The chip package assemblies advantageously increase product yield and improve reliability by minimizing electrical short caused by liquid metal TIM contact with surface mounted components. Additionally, examples of the stiffener assemblies disclosed can be efficiently assembled by attaching a top portion to a bottom portion. In this respect, the cavity housing the surface mounted components can be formed without the use of a costly etching process for a stainless-steel stiffener ring. Further, because the top portion 132 is attached to the bottom portion 131 at a height above the surface mounted components 104, the potential for damaging the surface mounted components 104 during attachment of the stiffener assembly 130 is minimized.

While the foregoing is directed to embodiments of the present invention, other and further embodiments of the invention may be devised without departing from the basic scope thereof, and the scope thereof is determined by the claims that follow.

What is claimed is:

1. A chip package assembly, comprising:
a package substrate having a top surface;
an IC die mounted to the top surface of the package substrate;
a stiffener assembly having a top portion and a bottom portion, the bottom portion mounted on the top surface of the package substrate
a dam disposed on the top surface of the package substrate, the dam and the bottom portion defining a cavity; and
a surface mounted component mounted on the package substrate and inside the cavity, the top portion mounted on the bottom portion and disposed above the cavity.

2. The chip package assembly of claim 1, wherein the dam and the bottom portion are independently disposed on the top surface of the package substrate.

3. The chip package assembly of claim 1, wherein the dam is integral with the bottom portion.

4. The chip package assembly of claim 1, wherein the dam is integral with the top portion and extends downward from the top portion.

5. The chip package assembly of claim 1, wherein the bottom portion has a height equal to or greater than a height of the surface mounted component.

6. The chip package assembly of claim 1, wherein the dam has a height equal to or greater than a height of the surface mounted component.

7. The chip package assembly of claim 1, further comprising a thermal interface material disposed above the IC die.

8. The chip package assembly of claim 7, wherein the thermal interface material comprises a liquid metal.

9. The chip package assembly of claim 1, wherein the dam is formed on the top surface of the package substrate.

10. The chip package assembly of claim 1, wherein the chip package assembly includes a plurality of cavities, each cavity including one or more surface mounted components disposed therein.

11. The chip package assembly of claim 10, wherein the top portion of the stiffener assembly covers at least one of the plurality of cavities.

12. A method for fabricating a chip package assembly, the method comprising:
coupling an IC die to a top surface of a package substrate;
coupling a surface mounted component on the package substrate;
disposing a bottom portion of a stiffener assembly on the top surface of the package substrate;
disposing a dam on the package substrate, wherein the dam and the bottom portion define a cavity housing the surface mounted component; and
mounting a top portion of the stiffener assembly on the bottom portion to enclose the cavity.

13. The method of claim 12, wherein the dam is disposed on the package substrate before the bottom portion.

14. The method of claim 13, further comprising mounting the top portion of the stiffener assembly on the dam.

15. The method of claim 12, wherein the dam is integral with the top portion and extends downward from the top portion.

16. The method of claim 15, wherein mounting the top portion of the stiffener assembly includes mounting the dam to the package substrate.

17. The method of claim 12, wherein the dam is integral with the bottom portion and the cavity is formed in the bottom portion prior to disposing the bottom portion on the package substrate.

18. The method of claim 12, further comprising a liquid metal thermal interface material disposed above the IC die.

19. A chip package assembly, comprising:
a package substrate having a top surface;
an IC die mounted to the top surface of the package substrate;
a stiffener mounted on the top surface of the package substrate
a dam disposed on the top surface of the package substrate, the dam and the stiffener defining a cavity;
a surface mounted component mounted on the package substrate and inside the cavity; and
a lid disposed on the stiffener and the IC die, the lid covering a top of the cavity.

20. The chip package assembly of claim 19, further comprising a liquid metal thermal interface material disposed between the lid and the IC die.
